(19) United States
(12) Patent Application Publication
(10) Pub. No.: US 2026/0195046 A1
(43) Pub. Date: Jul. 9, 2026

(54) MANAGING LATENCIES IN MEMORY SYSTEMS

(71) Applicant: Yangtze Memory Technologies Co., Ltd., Wuhan (CN)

(72) Inventors: Weilin LIU, Wuhan (CN); Haochiang HSU, Wuhan (CN)

(21) Appl. No.: 19/028,375

(22) Filed: Jan. 17, 2025

(30) Foreign Application Priority Data
Jan. 9, 2025 (CN) 202510035409.5

(51) Int. Cl. G06F 3/06

(52) U.S. Cl. CPC G06F 3/0611; G06F 3/0659; G06F 3/0679

(57) ABSTRACT

Methods, apparatus, and systems for managing parity data generation are provided. In one aspect, a memory system includes a memory device, and a memory controller coupled to the memory device. The memory controller is configured to perform operations including receiving a first input/output (IO) command from a host, and in response to determining that a latency corresponding to the first IO command is greater than or equal to a threshold, sending, to the host, a response indicating that the first IO command is completed.

### CROSS-REFERENCE TO RELATED APPLICATIONS

This application claims priority to Chinese Patent Application No. 202510035409.5, filed on Jan. 9, 2025, which is hereby incorporated by reference in its entirety.

### TECHNICAL FIELD

The present disclosure generally relates to memory devices and memory systems, and in particular, to managing parity data in memory systems.

### BACKGROUND

A memory system can include one or more memory devices and a memory controller that manages the data stored in the one or more memory devices and communicates with a host. The host can send commands, for example, read commands and write commands, to the memory system to control operations of the memory system.

### SUMMARY

The present disclosure involves methods, apparatuses, and systems for managing latencies in memory systems. One aspect of the present disclosure features a memory system including a memory device and a memory controller coupled to the memory device. The memory controller is configured to perform operations including receiving a first input/output (IO) command from a host; and in response to determining that a latency corresponding to the first IO command is greater than or equal to a threshold, sending, to the host, a response indicating that the first IO command is completed.

In some implementations, the latency corresponding to the first IO command is determined based on a difference between a current time and a time when the first IO command is received.

In some implementations, the threshold is pre-set based on at least one of a type of the first IO command; or a quality of service (QoS) requirement of the host.

In some implementations, the operations include receiving a second IO command from the host; and in response to determining that the second IO command is completed, sending a response indicating that the second IO command is completed.

In some implementations, the operations include in response to determining that one or more operations indicated by the first IO command are performed by the memory system, generating a completion queue entry (CQE) corresponding to the first IO command; and in response to determining that the latency corresponding to the first IO command is less than the threshold, adding the CQE to a pending queue.

In some implementations, the operations include determining whether the latency has reached the threshold based on periodically checking the CQE in the pending queue.

In some implementations, the memory controller includes a cache that stores the time when the first IO command is received; a register that stores the threshold; and one or more circuits configured to determine whether the latency is greater than or equal to the threshold.

In some implementations, the one or more circuits include a first circuit configured to determine the threshold based on a type of the first IO command; a second circuit configured to calculate the latency of the first IO command; and a third circuit configured to compare the threshold and the latency.

In some implementations, the memory controller includes a fourth circuit configured to determine whether the pending queue is empty.

Another aspect of the present disclosure features a memory controller. The memory controller includes one or more processors and an interface. The one or more processors are configured to perform operations including receiving, through the interface from a host, a first input/output (IO) command; and in response to determining that a latency corresponding to the first IO command is greater than or equal to a threshold, sending, through the interface to the host, a response indicating that the first IO command is completed.

In some implementations, the latency corresponding to the first IO command is determined based on a difference between a current time and a time when the first IO command is received.

In some implementations, the threshold is pre-set based on at least one of a type of the first IO command; or a quality of service (QoS) requirement of the host.

In some implementations, the operations include receiving a second IO command from the host; and in response to determining that the second IO command is completed, sending a response indicating that the second IO command is completed.

In some implementations, the operations include: in response to determining that one or more operations indicated by the first IO command are performed by the memory system, generating a completion queue entry (CQE) corresponding to the first IO command; and in response to determining that the latency corresponding to the first IO command is less than the threshold, adding the CQE to a pending queue.

In some implementations, the memory controller includes a cache that stores the time when the first IO command is received; a register that stores the threshold; and one or more circuits configured to determine whether the latency is greater than or equal to the threshold.

In some implementations, the one or more circuits include a first circuit configured to determine the threshold based on a type of the first IO command; a second circuit configured to calculate the latency of the first IO command; and a third circuit configured to compare the threshold and the latency.

In some implementations, the memory controller includes a fourth circuit configured to determine whether the pending queue is empty.

Another aspect of the present disclosure features a method of operating a memory system. The method includes receiving a first input/output (IO) command from a host; and in response to determining that a latency corresponding to the first IO command is greater than or equal to a threshold, sending, to the host, a response indicating that the first IO command is completed.

In some implementations, the method further includes receiving a second IO command from the host; and in response to determining that the second IO command is completed, sending a response indicating that the second IO command is completed.

In some implementations, the method further includes in response to determining that one or more operations indicated by the first IO command are performed by the memory system, generating a completion queue entry (CQE) corresponding to the first IO command; and in response to determining that the latency corresponding to the first IO command is less than the threshold, adding the CQE to a pending queue.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates a block diagram of an example system having a memory system, according to some aspects of the present disclosure.

FIGS. 2A-2B illustrate example storage products, according to some aspects of the present disclosure.

FIG. 3 illustrates an example of a schematic diagram of a memory device including peripheral circuits, according to some aspects of the present disclosure.

FIG. 4 illustrates some example peripheral circuits, according to some aspects of the present disclosure.

FIG. 5 illustrates an example of a block diagram of an example memory controller interacting with a host and a memory device, according to some aspects of the present disclosure.

FIG. 6 illustrates an example latency determination circuit, according to some aspects of the present disclosure.

FIG. 7 illustrates an example process of managing latencies in a memory system, according to some aspects of the present disclosure.

FIG. 8 illustrates a flowchart of an example process of operating a memory system, according to some aspects of the present disclosure.

FIG. 9 compares latencies of input/output (IO) commands during a period of time under the scenario where the memory controller includes a latency determination circuit and the scenario where the memory controller does not include a latency determination circuit, according to some aspects of the present disclosure.

Like reference numbers and designations in the various drawings indicate like elements.

### DETAILED DESCRIPTION

A host system can utilize a memory system that includes a memory controller and one or more memory components, such as memory devices that store data, that are controlled by the memory controller. The host system can provide data to be stored in the memory system and can request data to be retrieved from the memory system. Quality of service (QoS) is a key evaluation factor for memory systems. QoS metrics can include, for example, latency/response time, system throughput, and other measurements. Different QoS latency metrics can be established for various applications. For example, a memory system can have a QoS target of 99.9%, such that latencies of 99.9% of input/output (IO) commands are expected to be shorter than a target latency. For another example, a memory system can have a QoS target of 99.999%, such that latencies of 99.999% of input/output (IO) commands are expected to be shorter than the target latency.

In some cases, in response to determining that an IO command is completed, the memory controller can send, to the host, a response indicating that the IO command is completed (e.g., immediately after the IO command is completed). When the host determines the QoS metrics of the memory system, the latency corresponding to the IO command can be determined based on a difference between the time when the host receives the response indicating command completion and the time when the host sends the IO command. In some cases, there can be a large fluctuation among latencies corresponding to IO commands received during a period of time, which may make QoS metrics unstable and affect user experience.

The present disclosure provides techniques to manage latencies in a memory system. In some implementations, in response to determining that an IO command is completed, the memory controller can determine whether a latency corresponding to the IO command has reached a pre-set threshold. In response to determining that the latency has reached the pre-set threshold, the memory controller can send a response to the host to indicate command completion. In response to determining that the latency has not reached the pre-set threshold, the memory controller can hold off sending the response indicating command completion, until the latency reaches the pre-set threshold.

The described techniques can achieve one or more technical effects. For example, from the host perspective, there can be a smaller fluctuation among latencies corresponding to IO commands over a period of time, which can make QoS metrics of the memory system more stable. For another example, due to smaller fluctuations in latencies and better stability in QoS metrics, user experience can be enhanced. Further, the described techniques can be realized with simple adjustments to the circuity and algorithms of the memory controller, which is a cost-effective way to improve the efficiency of the memory system. In some implementations, additional or different technical effects can be achieved.

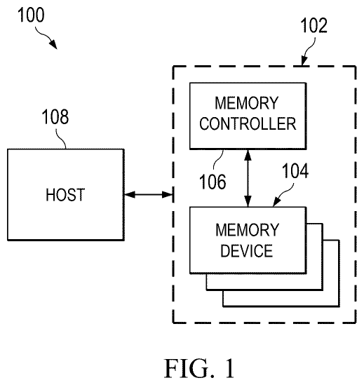

FIG. 1 illustrates a block diagram of an example system 100 having a memory system 102, according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. In some implementations, the system 100 can be a server, such as a data center server or a cloud server, that provides centralized data storage, management and distribution. As shown in FIG. 1, the system 100 can include a host 108 and a memory system 102 coupled to the host 108. The memory system 102 can have one or more memory devices 104 and a memory controller 106. The host 108 can include one or more processors of an electronic device. The processor can be a central processing unit (CPU), or a system-on-chip (SoC), such as an application processor (AP). The host 108 can be configured to send or receive data and commands to or from the memory system 102, to control operations of the memory system 102.

The memory device 104 can be any memory device disclosed in the present disclosure, such as a NAND Flash memory device. It is noted that the NAND Flash is only one example of memory device for illustrative purposes. It can include any suitable solid-state, non-volatile memory, e.g., NOR Flash, Ferroelectric RAM (FeRAM), Phase-change memory (PCM), Magne-to-resistive random-access memory (MRAM), Spin-transfer torque magnetic random-access memory (STT-RAM), or Resistive random-access memory (RRAM), etc. In some implementations, memory device 104 includes a three-dimensional (3D) NAND Flash memory device.

The memory controller 106 can be implemented by microprocessors, microcontrollers (a.k.a. microcontroller units (MCUs)), digital signal processors (DSPs), application-specific integrated circuits (ASICs), field-programmable gate arrays (FPGAs), programmable logic devices (PLDs), state machines, gated logic, discrete hardware circuits, and other suitable hardware, firmware, and/or software configured to perform the various functions described below in detail.

The memory controller 106 is coupled to the memory device 104 and to the host 108, and is configured to control the memory device 104, according to some implementations. The memory controller 106 can manage the data stored in the memory device 104 and can communicate with the host 108. In some implementations, the memory controller 106 is designed for operating in a low duty-cycle environment, such as secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, logical-to-physical mapping management, wear leveling, etc. In some implementations, the memory controller 106 is further configured to process error correction codes (ECCs) with respect to the data read from or written to the memory device 104. Any other suitable functions can be performed by the memory controller 106 as well, for example, formatting the memory device 104.

The memory controller 106 can communicate with an external device (e.g., the host 108) according to a particular communication protocol. For example, the memory controller 106 can communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc. The memory controller 106 is configured to receive and transmit a command to and from the host 108, and execute or perform multiple functions and operations provided in the present disclosure, which will be described later.

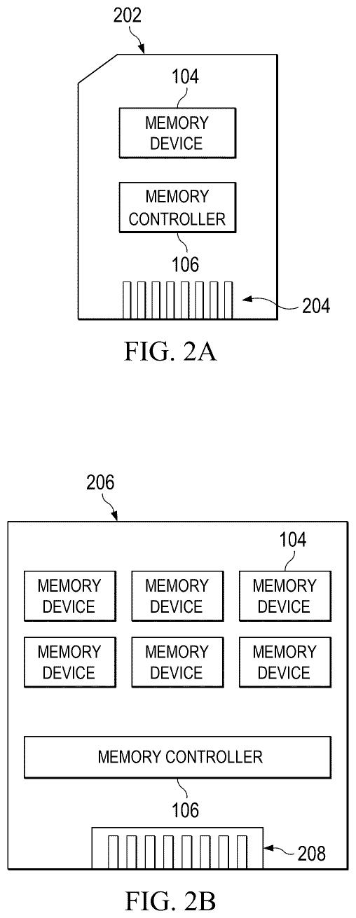

The memory controller 106 and the one or more memory devices 104 can be integrated into various types of storage devices. For example, the memory controller 106 and the one or more memory devices 104 can be packaged in a universal Flash storage (UFS) package or an eMMC package. In one example as shown in FIG. 2A, the memory controller 106 and a single memory device 104 can be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 204 coupling the memory card 202 with a host (e.g., host 108 in FIG. 1). In another example as shown in FIG. 2B, the memory controller 106 and multiple memory devices 104 can be integrated into an SSD 206. The SSD 206 can further include an SSD connector 208 that couples the SSD 206 with a host (e.g., host 108 in FIG. 1). In some implementations, the storage capacity and/or the operation speed of the SSD 206 is greater than those of the memory card 202.

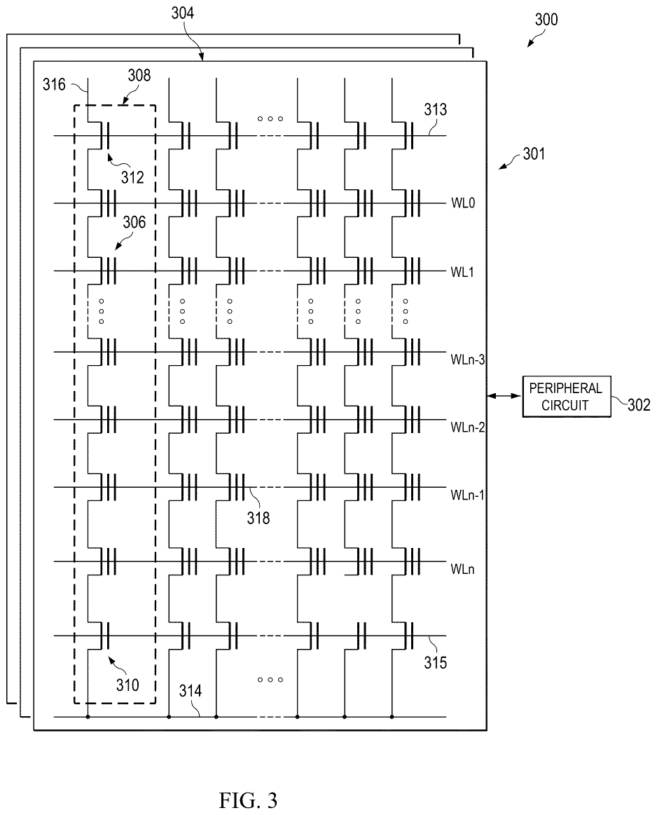

FIG. 3 illustrates an example of a schematic diagram of a memory device 300 including peripheral circuits, according to some aspects of the present disclosure. The memory device 300 can include a memory cell array 301 and peripheral circuits 302 coupled to the memory cell array 301. The memory cell array 301 can be a NAND Flash memory cell array in which memory cells 306 are provided in the form of an array of memory strings 308 each extending vertically above a substrate (not shown in FIG. 3). In some implementations, each memory string 308 includes a plurality of memory cells 306 coupled in series and stacked vertically. Each memory cell 306 can hold a continuous, analog value, such as an electrical voltage or charge that depends on the number of electrons trapped within a storage layer of the memory cell 306. The logic state (i.e., data) of each memory cell 306 in a memory block 304 can be determined based on the threshold voltage Vth of the memory cell 306. Each memory cell 306 can be a floating gate type memory cell including a floating-gate transistor, or a charge trap type memory cell including a charge-trap transistor.

In some implementations, each memory cell 306 is a single-level cell (SLC) with two possible memory states that can store one bit of data. For example, the first memory state “0” can correspond to a first range of voltages, and the second memory state “1” can correspond to a second range of voltages. In some implementations, each memory cell 306 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 3, each memory string 308 can include a source select gate (SSG) 310 at its source end and a drain select gate (DSG) 312 at its drain end. The SSG 310 and the DSG 312 can be configured to activate selected memory strings 308 (columns of the array) during read and program operations. In some implementations, the sources of memory strings 308 in the same memory block 304 are coupled through a same source line (SL) 314, e.g., a common SL. In other words, memory strings 308 in the same memory block 304 have an array common source (ACS), according to some implementations. The DSG 312 of each memory string 308 is coupled to a respective bit line 316 from which data can be read or written via an output bus (not shown), according to some implementations. In some implementations, each memory string 308 is configured to be selected or deselected by applying a select voltage (e.g., above the threshold voltage of the transistor having the DSG 312) or a deselect voltage (e.g., 0 V) to the respective DSG 312 through one or more DSG lines 313, and/or by applying a select voltage (e.g., above the threshold voltage of the transistor having the SSG 310) or a deselect voltage (e.g., 0 V) to the respective SSG 310 through one or more SSG lines 315.

As shown in FIG. 3, memory strings 308 can be organized into multiple memory blocks 304, each of which can have a common SL 314 coupled to the ACS. In some implementations, each memory block 304 can serve as a basic data unit for erase operations, such that memory cells 306 on the same memory block 304 are erased at the same time. To erase memory cells 306 in a selected memory block 304, the SL 314 coupled to the selected memory block 304 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 306 of adjacent memory strings 308 can be coupled through word lines 318. The word line 318 can select which row of memory cells 306 is affected by read and program operations. Each word line 318 can include a gate line coupled to a plurality of control gates (gate electrodes) of a plurality of memory cells 306. Example word lines shown in FIG. 3 are between one or more DSG lines 313 and one or more SSG lines 315.

In some implementations, the memory cells 306 of adjacent memory strings 308 can be coupled through word lines 318. The word line 318 can select which row of memory cells 306 is affected by read and program operations. In some implementations where memory cells 306 are SLCs, one row of memory cells 306 can store one logical page of data, and therefore corresponds to one logical page. In some implementations where memory cells 306 are MLCs, one row of memory cells 306 can store two logical pages of data, and therefore corresponds to two logical pages. In some implementations where memory cells 306 are TLCs, one row of memory cells 306 can store three logical pages of data, and therefore corresponds to three logical pages. In some implementations where memory cells 306 are QLCs, one row of memory cells 306 can store four logical pages of data, and therefore corresponds to four logical pages.

Each word line 318 can include a gate line coupled to a plurality of control gates (gate electrodes) of a plurality of memory cells 306. Example word lines shown in FIG. 3 include WLO, WL1, . . . , WLn−2, WLn−1, and WLn that are between DSG line 313 and SSG line 315. In some implementations, the word lines can further include dummy word lines coupled to dummy memory cells.

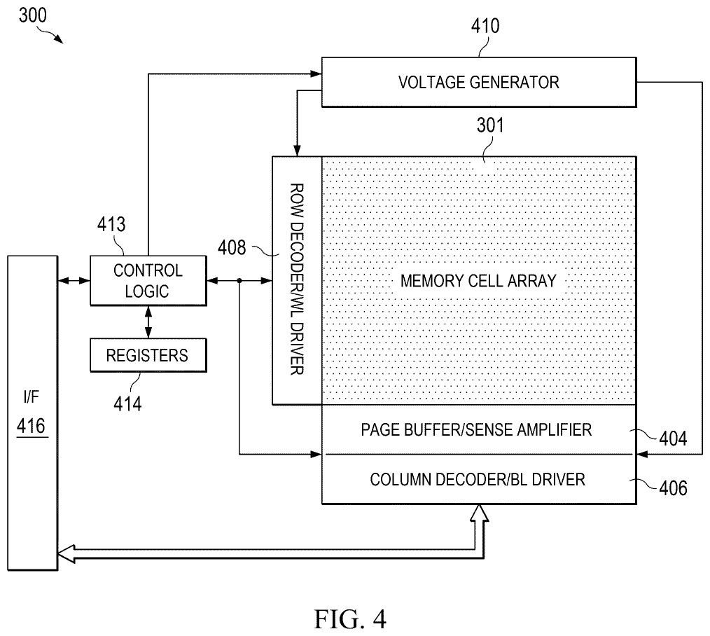

FIG. 4 illustrates some example peripheral circuits 302, according to some aspects of the present disclosure. The peripheral circuits 302 can be coupled to the memory array 301 through bit lines 316, word lines 318, source lines 314, SSG lines 315, and DSG lines 313. The peripheral circuits 302 can include any suitable analog, digital, and mixed-signal circuits for facilitating the operations of the memory array 301 by applying and sensing voltage signals and/or current signals to and from each target memory cell 306 through bit lines 316, word lines 318, source lines 314, SSG lines 315, and DSG lines 313. The peripheral circuits 302 can include various types of peripheral circuits formed using metal-oxide-semiconductor (MOS) technologies. The example peripheral circuits 302 include a page buffer/sense amplifier 404, a column decoder/bit line driver 406, a row decoder/word line driver 408, a voltage generator 410, control logic 412, registers 414, an interface 416, and a data bus. In some examples, additional peripheral circuits not shown in FIG. 4 may be included as well.

The page buffer/sense amplifier 404 can be configured to read and program (write) data from and to memory array 301 according to the control signals from control logic 412. In an example, the page buffer/sense amplifier 404 may store one page of program data (write data) in the memory array 301. In another example, the page buffer/sense amplifier 404 may perform program verify operations to ensure that the data have been properly programmed into memory cells 306 coupled to selected word lines 418. In still another example, the page buffer/sense amplifier 404 may also sense the low power signals from the bit line 316 that represents a data bit stored in memory cell 306, and amplify the small voltage swing to recognizable logic levels in a read operation. The column decoder/bit line driver 406 can be configured to be controlled by the control logic 412 and select one or more columns of memory cells by applying bit line voltages generated from the voltage generator 410.

The row decoder/word line driver 408 can be configured to be controlled by the control logic 412 and select/deselect memory blocks of the memory array 301 and select/deselect word lines 418 of the memory block. The row decoder/word line driver 408 can be further configured to drive word lines 418 using word line voltages generated from the voltage generator 410. In some implementations, the row decoder/word line driver 408 can also select/deselect and drive SSG lines 315 and DSG lines 313. As described below in detail, the row decoder/word line driver 408 is configured to apply a program voltage to selected word line 418 in a program operation on memory cell 306 coupled to selected word line 418.

The voltage generator 410 can be configured to be controlled by the control logic 412 and generate the word line voltages (e.g., read voltage, program voltage, pass voltage, local voltage, verify voltage, etc.), bit line voltages, and source line voltages to be supplied to the memory array 301.

The control logic 412 can be coupled to each circuit described above and configured to control the operations of each circuit. The registers 414 can be coupled to the control logic 412 and include status registers, command registers, and address registers for storing status information, command operation codes (OP codes), and command addresses for controlling the operations of each peripheral circuit.

The interface 416 can be coupled to the control logic 412 and act as a control buffer to buffer and relay control commands received from a host (not shown) to the control logic 412 and status information received from the control logic 412 to the host. The interface 416 can also be coupled to the column decoder/bit line driver 406 via a data bus, and act as a data input/output (I/O) interface and a data buffer to buffer and relay data to and from the memory array 301.

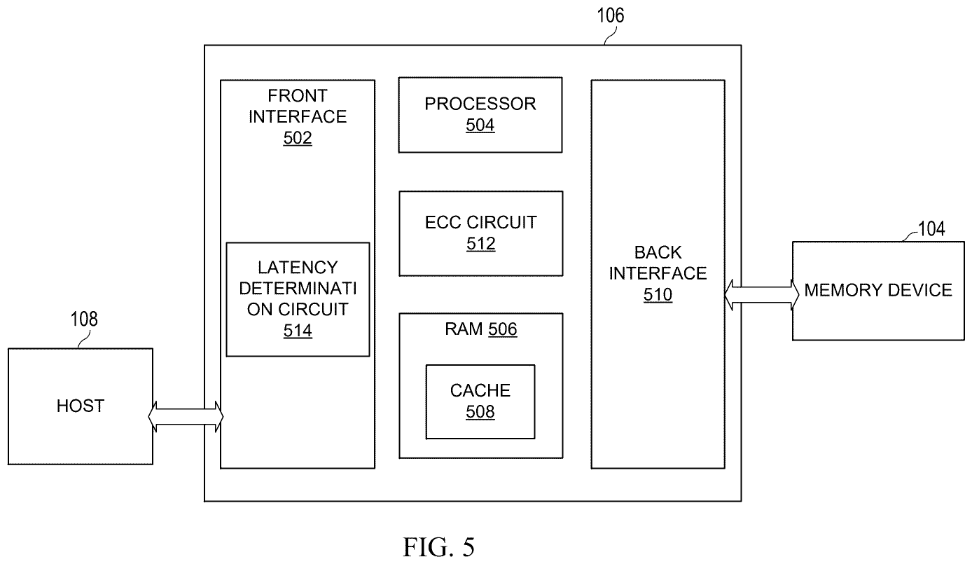

FIG. 5 illustrates an example of a block diagram of a memory controller 106 interacting with a host 108 and a memory device 104, according to some aspects of the present disclosure.

The memory controller 106 can include a front interface 502, one or more processors 504, a Random-Access Memory (RAM) 506, and a back interface 510, and an error-correction code (ECC) circuit 512. The RAM 506 can include one or caches 508. In some examples, additional components not shown in FIG. 5 may be included in the memory controller 106 as well.

The front interface 502 can be configured to handle communications between the host 108 and the memory controller 106. In some implementations, the front interface 502 can communicate with the host 108 according to a particular communication protocol. For example, the front interface 502 can communicate with the host 108 through at least one of various interface protocols, such as a Non-Volatile Memory Express (NVMe) protocol, a Computer Express Link (CXL) protocol, a USB protocol, an MMC protocol, a PCI protocol, a PCI-E protocol, an ATA protocol, a serial-ATA protocol, a parallel-ATA protocol, a SCSI protocol, an ESDI protocol, an IDE protocol, a Firewire protocol, etc. In some implementations, the front interface 502 can receive an input/output (IO) command from the host 108. The processor 504 or the back interface 510 can generate one or more commands corresponding to the IO command, and the back interface 510 can send the one or more commands to the memory device 104, so that the memory device 104 can perform the operation instructed by the host 108 in the IO command. Examples of an IO command can include, but are not limited to, a read command to read data stored in the memory device 104, an erase command to erase the data in the memory device 104, a write (program) command to write new data into the memory device 104, a reformatting command to reformat the memory device 104, or any other suitable command. In some implementations, the front interface 502 can send a response corresponding to an IO command. The response indicates to the host 108 that the IO command has been successfully completed, or that an error occurred when executing the IO command. In some implementations, the front interface 502 can receive data from the back interface 510, and send the data to the host 108.

The back interface 510 can be configured to send commands to the memory device 104, where the commands correspond to the IO command received by the front interface 502, so that the memory device 104 can perform the operation instructed by the host 108 in the IO command. In some implementations, the back interface 510 communicates with the memory device 104 through a different protocol (e.g., an ONFi protocol, a Toggle DDR protocol) from the protocol between the host 108 and the front interface 502. For example, the back interface 510 can be configured to send commands to control operations of the memory device 104 (e.g., read, erase, or program operations), where the operations are indicated by the host 108 in IO commands (e.g., a read command, an erase command, or a program command).

The ECC circuit 512 is configured to process error correction codes with respect to the data read from or written to the memory device 104. Example error correction codes can include, but are not limited to, Hamming codes, Reed-Solomon codes, low-density parity check (LDPC) codes, etc. In some implementations, the ECC circuit 512 includes an LPDC encoder configured to generate parity data based on LDPC codes for user data received from the host 108, so that both the user data and the parity data can be sent to the memory device 104 for storage. The ECC circuit 512 can further include an LDPC decoder configured to decode data comprising the user data and the parity data. The ECC circuit can determine whether data stored in the block is read successfully (e.g., with no errors). If the data stored in the block is read successfully, the back interface 510 can forward the data to the front interface 502, so that the front interface 502 can return the data to the host 108. However, if the data stored in the memory block is not read successfully, the back interface 510 can generate data describing a read error on the memory block.

The one or more processors 504 are configured to control operations of the memory controller 106. The one or more processors 504 are configured to control a read operation, a program operation, an erase operation, or other operations of the memory device 104. In some implementations, the one or more processors 504 can function as a flash translation layer (FTL). The FTL can be configured to manage various functions with respect to the data stored or to be stored in the memory device 104 including, but not limited to, address translation, bad-block management, wear leveling, garbage collection, etc.

The RAM 506 is configured to be used as an operation memory of the one or more processors 504, a cache memory between the memory device 104 and the host 108, and/or a buffer memory between the memory device 104 and the host 108. In some implementations, the RAM 506 can be a Static Random-Access Memory (SRAM). The RAM 506 can include one or more caches 508 configured to store parameters and intermediate results, for example, related to IO commands or ongoing operations. The RAM can further include one or more data buffers configured to temporarily hold data read from the memory device 104, before the data is sent to the host 108.

In some implementations, the memory controller 106 can include one or more registers configured to store configuration information of the memory system. For example, a register can store an indicator bit that indicates, in the next read operations, whether to read data from the memory device 104, or to read data directly from a data buffer in the RAM 506 (e.g., without reading the memory device 104). For another example, a register can store a target latency (e.g., 10 μs, 20 μs, 45 μs, or other suitable time length) corresponding to a specific type of IO command (e.g., read commands). The target latency can be pre-determined based on a requirement on overall QoS (e.g., QoS target of 99.9% of IO commands being completed within the target latency) by the host. In some implementations, different types of IO commands can have the same pre-determined target latency.

In some implementations, the front interface 502 can include a latency determination circuit 514. The latency determination circuit 514 can be configured to determine whether a latency corresponding to an IO command (e.g., the IO command that has been executed by the memory device 104) has reached a threshold (e.g., the target latency corresponding to the IO command). If the latency determination circuit 514 determines that the latency of the IO command has reached the threshold, the front interface 502 can send a response to the host 108 to indicate that the IO command has been completed. If the latency determination circuit 514 determines that the latency of the IO command has not yet reached the threshold, the front interface 502 can hold off sending the response to the host 108, until the latency reaches the threshold.

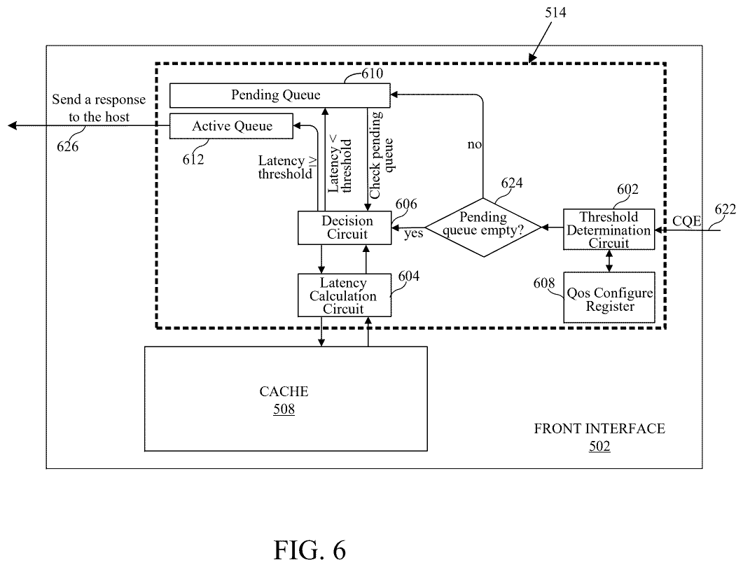

FIG. 6 illustrates an example latency determination circuit 514 included in a front interface 502 of a memory controller 106. The latency determination circuit 514 can include a threshold determination circuit 602, a latency calculation circuit 604, and a decision circuit 606.

In response to receiving an IO command from a host (e.g., the host 108 of FIG. 5) by the front interface (e.g., front interface 502 of FIG. 5), the back interface (e.g., back interface 510 of FIG. 5) can send, to the memory device, one or more commands that are generated based on the IO command, so that the memory device can perform the operation as instructed by the host in the IO command. When the memory device completes the operation, the back interface can generate a completion queue entry (CQE). The CQE represents the successful or failed completion of the corresponding IO command. The CQE can be a structured data packet that includes information such as a command identifier (which can link the CQE to the corresponding IO command), a status code (which can indicate whether the IO command has been completed successfully or if there are any error), a phase tag (which can indicate whether the CQE is new and valid), and/or other information fields.

At 622, the front interface 502 receives the CQE from the back interface.

In response to receiving the CQE, the threshold determination circuit 602 determines a threshold (e.g., target latency) corresponding to the IO command.

The threshold can be pre-set and stored in a register 608 of the memory controller 106. In some implementations, pre-set thresholds are different for different IO commands. For example, the pre-set threshold can be different for IO commands of different types. For instance, the threshold that is pre-set for read commands can be smaller than the threshold that is pre-set for program commands. For example, the threshold can be different for IO commands issued by different hosts. For instance, the memory device can be physically or virtually divided into multiple storage spaces, which are accessed by different hosts or applications. Different hosts or applications may have different QoS requirements, and the threshold for IO commands can be pre-set accordingly. In some implementations, the threshold can be pre-set according to other/more metrics.

The threshold determination circuit 602 can obtain the pre-set threshold corresponding to the IO command from a selected register 608 among a plurality of registers that store thresholds corresponding to different IO commands (e.g., based on the type of the IO commands).

At 624, the latency determination circuit 514 determines whether a pending queue 610 is empty. The pending queue 610 can store CQEs forwarded from the back interface 510 to the front interface 502. The CQEs in the pending queue 610 correspond to IO commands which have been completed, but of which the memory controller has not yet sent a response to the host to indicate command completion. In some implementations, the CQEs in the pending queue 610 can be ordered in the sequence in which the CQEs are received, or in the sequence in which the corresponding IO commands are received.

If the pending queue 610 is not empty, the current CQE can be added to the pending queue 610. If the pending queue 610 is empty, a decision circuit 606 can determine whether a latency of the IO command corresponding to the current CQE has reached (e.g., being greater than or equal to) the threshold. In some implementations, the decision circuit 606 can receive the threshold corresponding to the IO command from the threshold determination circuit 602, and receive the latency corresponding to the IO command from a latency calculation circuit 604.

The latency calculation circuit 604 can be configured to calculate the latency of the IO command based on a difference between a current time and a time when the IO command was received from the host. In some implementations, the time when the IO command was received from the host can be stored in the cache 508 of the RAM 506 of the memory controller 106.

If the decision circuit 606 determines that the latency of the IO command has reached the threshold, the CQE can be added to an active queue 612. The active queue 612 can store CQEs corresponding to IO commands which are completed and are ready to be reported to the host. At 626, the front interface 502 can send a response to the host to indicate that the IO command is completed. When the host determines QoS metrics of the memory system, the latency corresponding to the IO command can be determined based on a difference between the time when the host receives the response indicating command completion and the time when the host sent the IO command.

If the decision circuit 606 determines that the latency of the IO command has not reached (e.g., being less than) the threshold, the current CQE can be added to the pending queue 610.

The decision circuit 606 can periodically (e.g., every 1 μs, or other suitable cycle) check CQEs in the pending queue to determine whether, as more time has collapsed, the latencies of the IO commands corresponding to the CQEs have reached respective thresholds. A CQE corresponding to an IO command whose latency has reached the threshold can be moved from the pending queue 610 to the active queue 612. A CQE corresponding to an IO command whose latency still has not reached the threshold can remain in the pending queue 610 and wait to be checked during the next period.

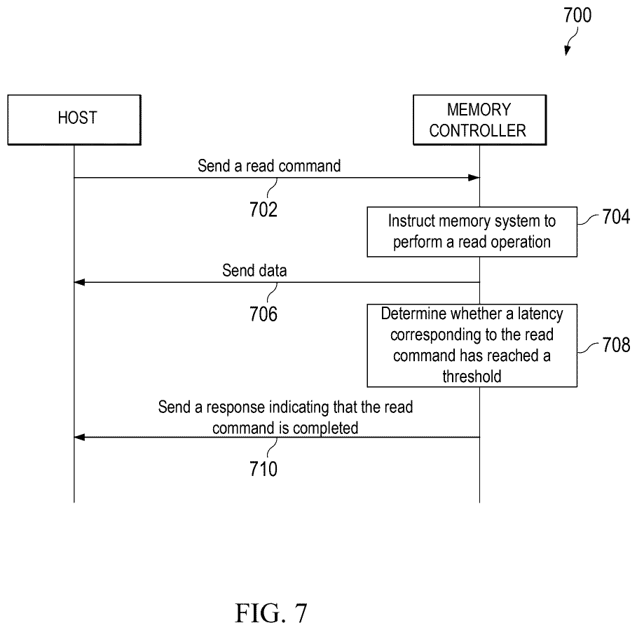

FIG. 7 illustrates an example process 700 of managing latencies in a memory system, according to some aspects of the present disclosure. In some cases, the host sends one IO command at one time (e.g., queue depth=1), such that the host does not send the next IO command until the host receives a response indicating that the current IO command is completed. In some cases, the host sends more than one IO command at one time (e.g., queue depth≥2). Under both scenarios, the memory controller can hold off sending a response indicating command completion until the latency corresponding to an IO command has reached the threshold. In the following, a read command is used as an example IO command for illustration.

At 702, the host sends a read command to the memory controller (e.g., to the front interface 502 of the memory controller 106 of FIGS. 5-6).

At 704, in response to receiving the read command, the memory controller can instruct the memory system to perform a read operation. In some implementations, the data to be read has already been stored in a data buffer of the memory controller (e.g., during a last read operation). In such case, at 706, the memory controller can send the data from the data buffer to the host. The read operation can take a relatively short time (e.g., 1-5 μs). In some implementations, the memory controller (e.g., the back interface 510 of the memory controller 106 of FIG. 5) can send commands (e.g., micro-sequences) to the memory device (e.g., the memory device 104 of FIG. 5) to read data from the memory device. At 706, the memory controller can send the data read from the memory device to the host. In such case, the read operation can take a relatively long time. For example, a read operation to read data from a memory device configured to operate in a single-level cell (SLC) mode may take approximately 20 μs; a read operation to read data from a memory device configured to operate in a triple-level cell (TLC) mode may take approximately 40 μs. A read operation that encounters a read failure and thus includes error correction may take longer.

At 708, when the read operation is completed, the memory controller (e.g., the latency determination circuit 514 of the memory controller 106 of FIGS. 5-6) can determine whether a latency corresponding to the read command has reached a threshold (e.g., pre-set as 45 μs, or other suitable time length).

At 710, in response to determining that the latency corresponding to the read command has reached the threshold, the memory controller sends a response to the host indicating that the read command is completed. In response to determining that the latency corresponding to the read command has not reached the threshold, the memory controller can hold off sending the response indicating command completion, until the latency reaches the threshold. When the host determines QoS metrics of the memory system, the latency corresponding to the read command is determined based on a difference between the time when the host receives the response indicating command completion at 710, and the time when the host sends the read command at 710. By implementing the process 700, from the host perspective, the latency corresponding to a read command that can be executed in a relatively short time (e.g., reading from the data buffer) can be prolonged, so that the range of latencies corresponding to read commands received during a time period can be reduced.

It should be noted that the process 700 can further include, after 710, or concurrently with 702-710, receiving a plurality of IO commands, performing operations indicated by each of the plurality of commands, and sending responses to the host indicating that respective IO commands have been completed in response to determining that their latencies have reached respective thresholds.

In some implementations, the process 700 is implemented with regard to a first group of IO commands (e.g., read commands, since read operations typically take a relatively short time). With regard to a second group of IO commands (e.g., write commands and erase commands, since write operations and erase operations typically take a relatively long time), the memory controller can receive an IO command from the host, and send a response indicating that command completion immediately after the IO command is completed (e.g., immediately after the operation is completed), without determining whether the latency corresponding to the IO command has reached a threshold. For example, with reference to FIG. 6, immediately after the front interface 502 receives a CQE corresponding to an IO command of the second group, the front interface 502 can send a response to the host indicating command completion.

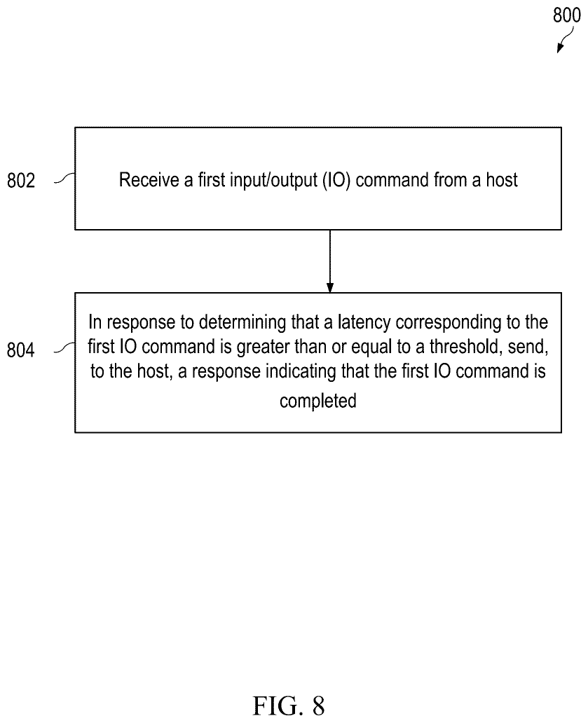

FIG. 8 illustrates a flowchart of an example process of operating a memory system, according to some aspects of the present disclosure. Process 800 can be performed by any suitable device or system as described herein, for example, according to the example techniques described with respect to FIGS. 1-7. For example, process 800 can be performed by a memory system (e.g., the memory system 102 of FIG. 1) that includes a memory device (e.g., the memory device 104 of FIGS. 1-2B and 5, the memory device 300 of FIG. 3) and a memory controller (e.g., the memory controller 106 of FIGS. 1-2B and 5-6).

At 802, the memory controller receives a first input/output (IO) command from the host. The first IO command can instruct the memory controller and/or the memory device to perform one or more specific operations.

At 804, in response to determining that a latency corresponding to the first IO command is greater than or equal to a threshold, the memory controller sends, to the host, a response indicating that the first IO command is completed.

In some implementations, the memory controller includes a latency determination circuit (e.g., the latency determination circuit 514 of FIGS. 5-6). The latency determination circuit can include a first circuit (e.g., the threshold determination circuit 602 of FIG. 6) configured to determine the threshold based on a type of the first IO command, a second circuit (e.g., the latency calculation circuit 604 of FIG. 6) configured to calculate the latency of the first IO command, and a third circuit (e.g., the decision circuit 606 of FIG. 6) configured to compare the threshold and the latency.

In some implementations, in response to determining that one or more operations indicated by the first IO command have been performed, the memory controller can generate a completion queue entry (CQE) corresponding to the first IO command. In response to determining that the latency corresponding to the first IO command is less than the threshold, the memory controller can add the CQE to a pending queue. In some implementations, the latency determination circuit further includes a fourth circuit configured to determine whether the pending queue is empty.

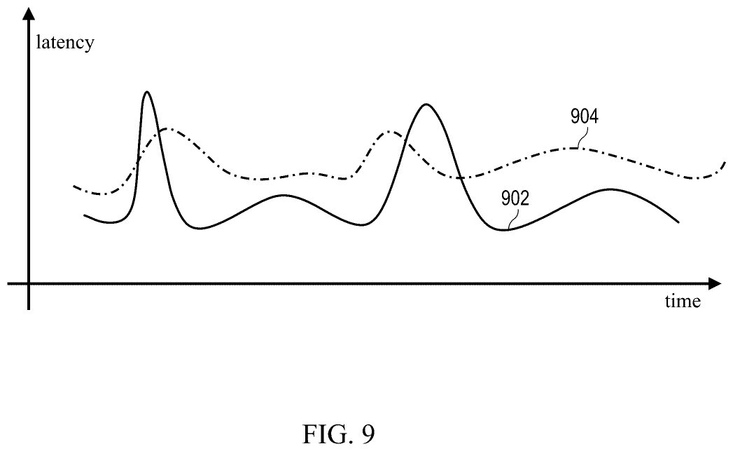

FIG. 9 compares latencies of IO commands during a period of time under the scenario where the memory controller includes a latency determination circuit (e.g., the latency determination circuit 514 of FIGS. 5-6), as illustrated by plot 904, and under the scenario where the memory controller does not include a latency determination circuit, as illustrated by plot 902, according to some aspects of the present disclosure.

Under the scenario where the memory controller does not include a latency determination circuit, the memory controller sends a response indicating command completion immediately after an IO command is completed. As shown in plot 902, the range of latencies corresponding to IO commands received during a period of time (e.g., a difference between the maximum latency and the minimum latency) can be large, which may result in the QoS metrics of the memory system being unstable over time.

Under the scenario where the memory controller includes a latency determination circuit, the memory controller can hold off sending a response indicating command completion until a latency corresponding to the IO command reaches a threshold. As shown in plot 904, the range of latencies corresponding to IO commands received during a period of time (e.g., a difference between the maximum latency and the minimum latency) can be reduced, which can result in the QoS metrics of the memory system being more stable overall. In some implementations, the host can adjust the pace of sending IO commands based on real-time QoS metrics, for example, sending IO commands at a faster pace when detecting short latencies. By including the latency determination circuit to prolong the latencies of IO commands that are completed in a relatively short time, the host is less likely to send IO commands at a quick pace which could result in a congestion of unfinished IO commands in the memory system. As such, the chance of experiencing long latencies can be reduced overall.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required to be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents. Accordingly, other implementations also are within the scope of the claims.

1. A memory system, comprising:
a memory device; and
a memory controller coupled to the memory device, wherein the memory controller comprises one or more processors and a front interface coupled to the one or more processors, wherein the front interface is configured to perform operations comprising:
receiving a first input/output (IO) command from a host;
determining whether a latency corresponding to the first IO command is greater than or equal to a threshold; and
in response to determining that the latency corresponding to the first IO command is greater than or equal to the threshold, sending, to the host, a response indicating that the first IO command is completed.

2. The memory system of claim 1, wherein the latency corresponding to the first IO command is determined based on a difference between a current time and a time when the first IO command is received.

3. The memory system of claim 1, wherein the threshold is pre-set based on at least one of:
a type of the first IO command; or
a quality of service (QoS) requirement of the host.

4. The memory system of claim 1, wherein the operations comprise:
receiving a second IO command from the host; and
in response to determining that the second IO command is completed, sending a response indicating that the second IO command is completed.

5. The memory system of claim 1, the operations comprise:
in response to determining that one or more operations indicated by the first IO command are performed by the memory system, generating a completion queue entry (CQE) corresponding to the first IO command; and
in response to determining that the latency corresponding to the first IO command is less than the threshold, adding the CQE to a pending queue.

6. The memory system of claim 5, wherein the operations comprise:
determining whether the latency has reached the threshold based on periodically checking the CQE in the pending queue.

7. The memory system of claim 2, wherein the memory controller comprises:
a cache that stores the time when the first IO command is received; and
a register that stores the threshold, and
wherein the front interface comprises:
one or more circuits configured to determine whether the latency is greater than or equal to the threshold.

8. The memory system of claim 7, wherein the one or more circuits comprise:
a first circuit configured to determine the threshold based on a type of the first IO command;
a second circuit configured to calculate the latency of the first IO command; and
a third circuit configured to compare the threshold and the latency.

9. The memory system of claim 5, wherein the front interface comprises:
a fourth circuit configured to determine whether the pending queue is empty.

10. A memory controller, comprising a front interface and one or more processors, wherein the front interface is configured to perform operations comprising:
receiving, from a host, a first input/output (IO) command;
determining whether a latency corresponding to the first IO command is greater than or equal to a threshold; and
in response to determining that the latency corresponding to the first IO command is greater than or equal to the threshold, sending, to the host, a response indicating that the first IO command is completed.

11. The memory controller of claim 10, wherein the latency corresponding to the first IO command is determined based on a difference between a current time and a time when the first IO command is received.

12. The memory controller of claim 10, wherein the threshold is pre-set based on at least one of:
a type of the first IO command; or
a quality of service (QoS) requirement of the host.

13. The memory controller of claim 10, wherein the operations comprise:
receiving a second IO command from the host; and
in response to determining that the second IO command is completed, sending a response indicating that the second IO command is completed.

14. The memory controller of claim 10, wherein the operations comprise:
in response to determining that one or more operations indicated by the first IO command are performed, generating a completion queue entry (CQE) corresponding to the first IO command; and
in response to determining that the latency corresponding to the first IO command is less than the threshold, adding the CQE to a pending queue.

15. The memory controller of claim 11, comprising:
a cache that stores the time when the first IO command is received; and
a register that stores the threshold, and
wherein the front interface comprises:
one or more circuits configured to determine whether the latency is greater than or equal to the threshold.

16. The memory controller of claim 15, wherein the one or more circuits comprise:
a first circuit configured to determine the threshold based on a type of the first IO command;
a second circuit configured to calculate the latency of the first IO command; and
a third circuit configured to compare the threshold and the latency.

17. The memory controller of claim 14, wherein the front interface comprises:
a fourth circuit configured to determine whether the pending queue is empty.

18. A method of operating a memory system, comprising:
receiving a first input/output (IO) command from a host;
determining, by a front interface of the memory system, whether a latency corresponding to the first IO command is greater than or equal to a threshold; and
in response to determining that the latency corresponding to the first IO command is greater than or equal to the threshold, sending, to the host, a response indicating that the first IO command is completed.

19. The method of claim 18, comprising;
receiving a second IO command from the host; and
in response to determining that the second IO command is completed, sending a response indicating that the second IO command is completed.

20. The method of claim 18, comprising;
in response to determining that one or more operations indicated by the first IO command are performed by the memory system, generating a completion queue entry (CQE) corresponding to the first IO command; and
in response to determining that the latency corresponding to the first IO command is less than the threshold, adding the CQE to a pending queue.
